(19) United States
(12) Patent Application Publication
(10) Pub. No.: US 2012/0106229 A1
(43) Pub. Date: May 3, 2012

(54) Semiconductor device

(75) Inventor: Chikara Kondo, Tokyo (JP)

(73) Assignee: Elpida Memory, Inc., Tokyo (JP)

(21) Appl. No.: 13/317,167

(22) Filed: Oct. 12, 2011

(30) Foreign Application Priority Data
Oct. 29, 2010 (JP) 2010-243144

(51) Int. Cl. G11C 5/06

(52) U.S. Cl. 365/63

(57) ABSTRACT

To include stacked plural core chips, each of which includes a first through silicon via for transferring write data and a second through silicon via for transferring read data, and an interface chip commonly connected to the core chips. The interface chip includes a data input/output terminal, an input buffer provided between the data input/output terminal and the first through silicon via, and an output buffer provided between the data input/output terminal and the second through silicon via. With this configuration, the write data and the read data are transferred through the different through silicon vias, whereby the collision of data is not caused even when continuous accesses are made to different ranks.

### BACKGROUND OF THE INVENTION

1. Field of the Invention

The present invention relates to a semiconductor device, and more particularly to a semiconductor device in which a front-end portion having an interface function and a back-end portion including a memory core are integrated on an individual semiconductor chip.

2. Description of Related Art

A semiconductor memory device such as a DRAM (Dynamic Random Access Memory) is frequently used as being mounted on a module substrate in plural numbers. The DRAMs mounted on the module substrate are sometimes classified into plural ranks (Rank) exclusively selected by a chip selection signal (see Japanese Patent Application Laid-Open No. 2010-134904). Since the DRAMs of different ranks are independently accessible, so long as there is no competition on a data bus, the use efficiency of the data bus can be enhanced by classifying the DRAMs on the module into the plural ranks.

On the other hand, there has recently been proposed a technique in which a so-called front-end portion performing an interface with a memory controller and a back-end portion including a memory core are integrated on an individual chip, and these chips are stacked to form a single semiconductor memory device (see Japanese Patent Application Laid-Open No. 2007-158237). According to this technique, in a core chip on which the back-end portion is integrated, a space that can be allocated to the memory core increases, whereby a storage capacity per 1 chip (per 1 core chip) can be increased. On the other hand, the interface chip on which the front-end portion is integrated can be manufactured by a process different from the process for the memory core, whereby a circuit can be formed with a high-speed transistor. Furthermore, plural core chips can be allocated to one interface chip, resulting in that a high-speed semiconductor memory device having extremely large capacity as a whole can be provided.

However, in a stacked semiconductor device, a through silicon via used for transferring read data or write data is commonly connected to plural core chips. Therefore, when the stacked plural core chips are classified into plural ranks, a competition of the read data and the write data might be generated on the through silicon via. In order to prevent the competition, an interval of issuing a command has to be increased so as not to cause the competition of data even in the access to the different rank. However, in this case, there arises a problem that the use efficiency of the data bus is reduced.

### SUMMARY

In one embodiment, there is provided a semiconductor device that includes: a plurality of first chips that are mutually stacked, each of the first chips including a first penetration electrode that transfers write data and a second penetration electrode that transfers read data, the first penetration electrodes formed on the first chips being electrically connected in common, and the second penetration electrodes formed on the first chips being electrically connected in common; and a second chip including a data input/output terminal, an input buffer coupled between the data input/output terminal and the first penetration electrodes, and an output buffer coupled between the data input/output terminal and the second penetration electrodes, wherein the input buffer receiving the write data from the data input/output terminal and outputting the write data to the first penetration electrodes, and the output buffer receiving the read data from the second penetration electrodes and outputting the read data to the data input/output terminal.

According to the present invention, the write data and the read data are transferred through a different signal path. Therefore, even if a reading operation is instructed to another rank immediately after a writing operation is instructed to a certain rank, the write data and the read data do not compete with each other on the through silicon via. Accordingly, the chips of different ranks are independently accessible, so long as a competition is not caused on the data bus on the control chip.

### BRIEF DESCRIPTION OF THE DRAWINGS

The above and other features and advantages of the present invention will be more apparent from the following description of certain preferred embodiments taken in conjunction with the accompanying drawings, in which:

FIG. 1 is a schematic cross-sectional view provided to explain the structure of a semiconductor device 10 according to the preferred embodiment of the present invention;

FIGS. 2A to 2C are diagrams showing the various types of through silicon via TSV provided in a core chip;

FIG. 3 is a cross-sectional view illustrating the structure of the through silicon via TSV of the type shown in FIG. 2A;

FIG. 4 is a schematic view for describing an address allocation in LRA-1 system;

FIG. 5 is a schematic view for describing an address allocation in LRA-2 system;

FIG. 6 is a schematic view for describing an address allocation in LRA-3 system;

FIG. 7 is a schematic view for describing an address allocation in PRA system;

FIG. 8 is a block diagram illustrating a configuration of the semiconductor device according to the preferable embodiment of the present invention;

FIG. 9 is a circuit diagram of an input buffer 31;

FIG. 10 is a circuit diagram of a chip address acquiring circuit 41;

FIG. 11 is a block diagram illustrating components, which are extracted from the semiconductor device, and which are involved with data transfer between an interface chip IF and core chips CC0 to CC7;

FIG. 12 is a timing chart for describing an operation of the semiconductor device 10; and

FIG. 13 is a block diagram illustrating a semiconductor device according to a modification.

### DETAILED DESCRIPTION OF THE EMBODIMENTS

Preferred embodiments of the present invention will be explained below in detail with reference to the accompanying drawings.

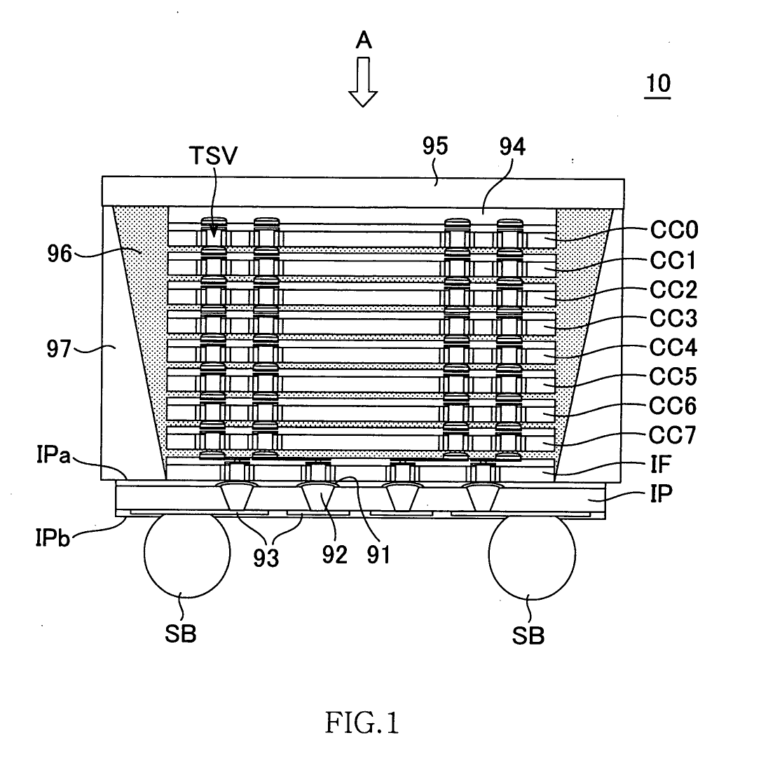

FIG. 1 is a schematic cross-sectional view provided to explain the structure of a semiconductor device 10 according to the preferred embodiment of the present invention.

As shown in FIG. 1, the semiconductor device 10 according to this embodiment has the structure where 8 core chips CC0 to CC7 (controlled chips) that have the same function and structure and are manufactured using the same manufacture mask, an interface chip IF (controlling chip) that is manufactured using a manufacture mask different from that of the core chips CC0 to CC7 and an interposer IP are laminated. The core chips CC0 to CC7 and the interface chip IF are semiconductor chips using a silicon substrate and are electrically connected to adjacent chips in a vertical direction through plural Through Silicon Vias (TSV) penetrating the silicon substrate. The through silicon via may be referred to as a penetration electrode. Meanwhile, the interposer IP is a circuit board that is made of a resin, and plural external terminals (solder balls) SB are formed in a back surface IPb of the interposer IP.

The core chips CC0 to CC7 are semiconductor chips from which a so-called front-end portion, which performs an interface with an outside, of circuit blocks included in a normal stand-alone SDRAM (Synchronous Dynamic Random Access Memory), is removed. That is, each of the core chips CC0 to CC7 is a semiconductor chip where only the circuit blocks belonging to the back end unit are integrated in principle. As the circuit blocks that are included in the front end unit, a parallel-serial converting circuit that performs parallel/serial conversion on input/output data between a memory cell array and a data input/output terminal and a DLL (Delay Locked Loop) circuit that controls input/output timing of data are exemplified, which will be described in detail below.

On the other hand, the interface chip IF is a semiconductor chip on which only the front-end portion of the circuit blocks included in the normal stand-alone SDRAM is integrated. The interface chip IF functions as a front-end portion common to 8 core chips CC0 to CC7. Accordingly, all of the external accesses are made through the interface chip IF, and data input and data output are made through the interface chip IF.

The interface chip IF functions as a common front end unit for the eight core chips CC0 to CC7. Accordingly, all external accesses are performed through the interface chip IF and inputs/outputs of data are also performed through the interface chip IF. In this embodiment, the interface chip IF is disposed between the interposer IP and the core chips CC0 to CC7. However, the position of the interface chip IF is not restricted in particular, and the interface chip IF may be disposed on the core chips CC0 to CC7 and may be disposed on the back surface IPb of the interposer IP. When the interface chip IF is disposed on the core chips CC0 to CC7 in a face-down manner or is disposed on the back surface IPb of the interposer IP in a face-up manner, the through silicon via TSV does not need to be provided in the interface chip IF. The interface chip IF may be disposed to be interposed between the two interposers IP.

The interposer IP functions as a rewiring substrate to increase an electrode pitch and secures mechanical strength of the semiconductor device 10. That is, an electrode 91 that is formed on a top surface IPa of the interposer IP is drawn to the back surface IPb via a through-hole electrode 92 and the pitch of the external terminals SB is enlarged by the rewiring layer 93 provided on the back surface IPb. In FIG. 1, only the two external terminals SB are shown. In actuality, however, three or more external terminals are provided. The layout of the external terminals SB is the same as that of the DDR3-type SDRAM that is determined by the regulation. Accordingly, the semiconductor memory device can be treated as one DDR3-type SDRAM from the external controller.

As shown in FIG. 1, a top surface of the uppermost core chip CC0 is covered by an NCF (Non-Conductive Film) 94 and a read frame 95. Gaps between the core chips CC0 to CC7 and the interface chip IF are filled with an underfill 96 and surrounding portions of the gaps are covered by a sealing resin 97. Thereby, the individual chips are physically protected.

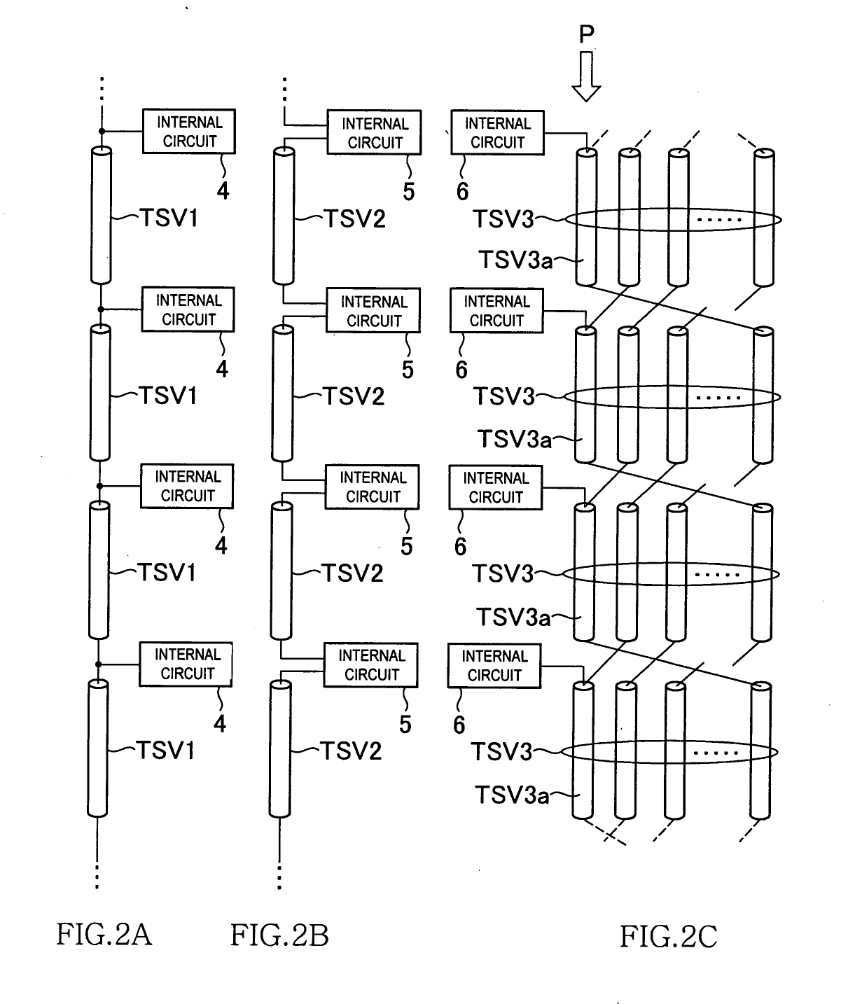

When most of the through silicon vias TSV provided in the core chips CC0 to CC7 are two-dimensionally viewed from a lamination direction, that is, viewed from an arrow A shown in FIG. 1, the through silicon vias TSV are short-circuited from the through silicon vias TSV of other layers provided at the same position. That is, as shown in FIG. 2A, the vertically disposed through silicon vias TSV1 that are provided at the same position in plain view are short-circuited, and one wiring line is configured by the through silicon via TSV1. The through silicon via TSV1 that are provided in the core chips CC0 to CC7 are connected to internal circuits 4 in the core chips, respectively. Accordingly, input signals (command signal, address signal, etc.) that are supplied from the interface chip IF to the through silicon vias TSV1 shown in FIG. 2A are commonly input to the internal circuits 4 of the core chips CC0 to CC7. Output signals (data etc.) that are supplied from the core chips CC0 to CC7 to the through silicon via TSV1 are wired-ORed and input to the interface chip IF.

Meanwhile, as shown in FIG. 2B, the apart of the through silicon vias TSV are not directly connected to the through silicon via TSV2 of other layers provided at the same position in plain view but are connected to the through silicon via TSV2 of other layers through the internal circuits 5 provided in the core chips CC0 to CC7. That is, the internal circuits 5 that are provided in the core chips CC0 to CC7 are cascade-connected through the through silicon via TSV2. This kind of through silicon via TSV2 is used to sequentially transmit predetermined information to the internal circuits 5 provided in the core chips CC0 to CC7. As this information, layer address information to be described below is exemplified.

Another part of the through silicon vias TSV is short-circuited from the through silicon vias TSV of other layer provided at the different position in plan view, as shown in FIG. 2C. With respect to this kind of through silicon vias TSV group 3, internal circuits 6 of the core chips CC0 to CC7 are connected to the through silicon via TSV3a provided at the predetermined position P in plain view. Thereby, information can be selectively input to the internal circuits 6 provided in the core chips. As this information, defective chip information to be described below is exemplified.

As such, as types of the through silicon vias TSV provided in the core chips CC0 to CC7, three types (TSV1 to TSV3) shown in FIGS. 2A to 2C exist. As described above, most of the through silicon vias TSV are of a type shown in FIG. 2A, and an address signal and a command signal, and the like are supplied from the interface chip IF to the core chips CC0 to CC7, through the through silicon via TSV1 of the type shown in FIG. 2A. Read data and write data are input to and output from the interface chip IF through the through silicon via TSV1 of the type shown in FIG. 2A. Meanwhile, the through silicon vias TSV2 and TSV3 of the types shown in FIGS. 2B and 2C are used to provide individual information to the core chips CC0 to CC7 having the same structure.

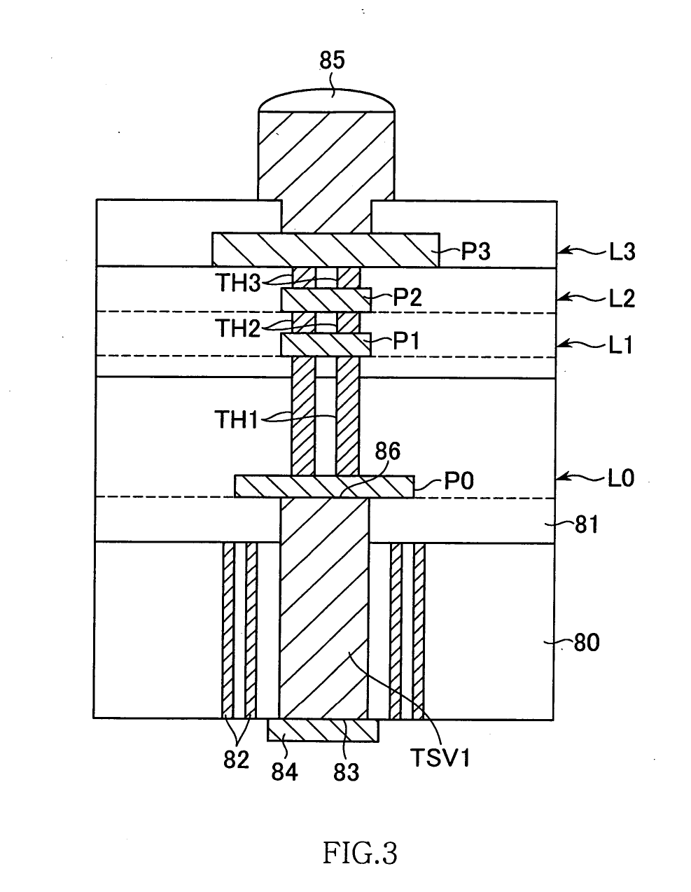

FIG. 3 is a cross-sectional view illustrating the structure of the through silicon via TSV1 of the type shown in FIG. 2A.

As shown in FIG. 3, the through silicon via TSV1 is provided to penetrate a silicon substrate 80 and an interlayer insulating film 81 provided on a surface of the silicon substrate 80. Around the through silicon via TSV1, an insulating ring 82 is provided. Thereby, the through silicon via TSV1 and a transistor region are insulated from each other. In an example shown in FIG. 3, the insulating ring 82 is provided double. Thereby, capacitance between the through silicon via TSV1 and the silicon substrate 80 is reduced.

An end 83 of the through silicon via TSV1 at the back surface of the silicon substrate 80 is covered by a back surface bump 84. The back surface bump 84 is an electrode that contacts a surface bump 85 provided in a core chip of a lower layer. The surface bump 85 is connected to an end 86 of the through silicon via TSV1, through plural pads P0 to P3 provided in wiring layers L0 to L3 and plural through-hole electrodes TH1 to TH3 connecting the pads to each other. Thereby, the surface bump 85 and the back surface bump 84 that are provided at the same position in plain view are short-circuited. Connection with internal circuits (not shown in the drawings) is performed through internal wiring lines (not shown in the drawings) drawn from the pads PO to P3 provided in the wiring layers L0 to L3.

Before detailed circuit structures of the interface chip IF and the core chips CC0 to CC7 are described, an address allocation in a semiconductor device 10 according to the present embodiment will be described.

The semiconductor device 10 according to the present embodiment can change the address allocation by a mode selection. There are roughly prepared an LRA (Logical Rank Address) system and a PRA (Physical Rank Address) system in the semiconductor device 10. The LRA system is an address allocation system in which plural banks mounted to the different core chips CC0 to CC7, respectively, are handled as one bank by a controller. On the other hand, the PRA system is an address allocation system in which each of the plural banks mounted to the respective core chips CC0 to CC7 is handled as one bank. In the present embodiment, there are three types in the LRA system. Each of three types is referred to as LRA-1 system, LRA-2 system, and LRA-3 system, for the sake of convenience. The respective systems will specifically be described below.

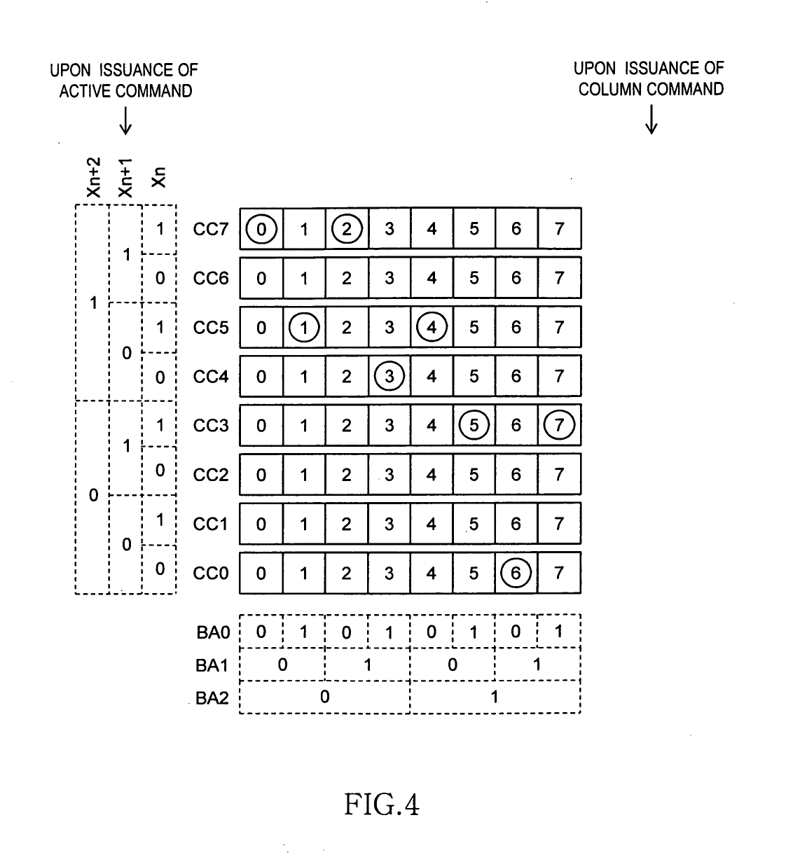

FIG. 4 is a schematic view for describing the address allocation in the LRA-1 system. In FIGS. 4 to 7, one square indicates a bank. Therefore, a single core chip includes banks 0 to 7.

As illustrated in FIG. 4, in the LRA-1 system, any one of the core chips CC0 to CC7 is selected based upon a part of an address signal, which is Xn+2, Xn+1, and Xn (chip address), supplied during a row-access (upon an issuance of an active command ACT), and anyone of banks 0 to 7 is selected based upon bank address signals BA0 to BA2 supplied during the row access and a column access. The controller recognizes 8 banks, included in the different core chips CC0 to CC7 and having the same number, as one bank.

In this system, the chip address is not supplied during the column access (upon the issuance of a column command). However, since the controller recognizes 8 banks, included in the different core chips CC0 to CC7 and having the same number, as one bank, the controller can identify to which one of the core chips CC0 to CC7 the column access is made during the column access, even if the chip address is not supplied. Because there is inevitably one core chip in which the bank designated upon the column access is in an active state.

For example, it is supposed that the encircled banks are in the active state in FIG. 4. If the designated bank upon the column access is the bank 0, the column access is made to the core chip CC7 in which the bank 0 is in the active state. If the designated bank upon the column access is the bank 1, the column access is made to the core chip CC5 in which the bank 1 is in the active state.

As described above, the selection of the core chips CC0 to CC7 is made during the row access in the LRA-1 system. The controller recognizes the core chips CC0 to CC7 as one DRAM, so that a chip selection signal (CS) to be used is also 1 bit. Therefore, the number of memory cells accessed by one row access becomes 1 kilobyte, and the number of the rank becomes 1.

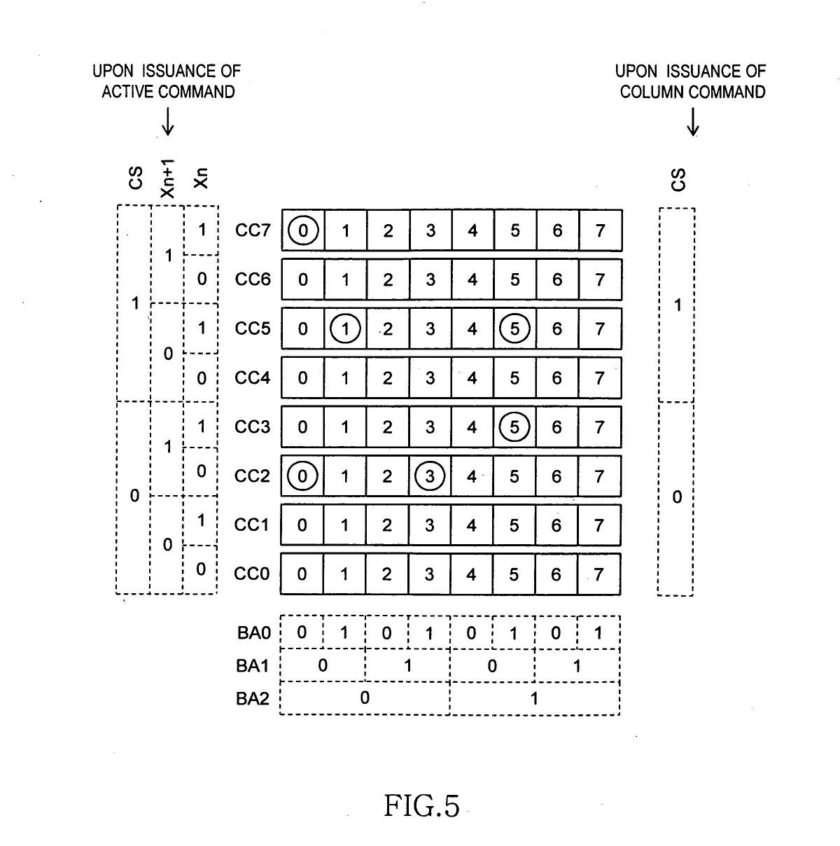

FIG. 5 is a schematic view for describing the address allocation in the LRA-2 system.

As illustrated in FIG. 5, in the LRA-2 system, the core chips CC0 to CC3 or the core chips CC4 to CC7 are selected based upon chip selection signals CS0 and CS1 of two bits, and any one of selected 4 core chips is selected based upon a part of an address signal, which is Xn+1, and Xn (chip address), supplied during a row-access. The bank address signals BA0 to BA2 are supplied during both the row access and the column access.

In this system, the core chips CC0 to CC3 or the core chips CC4 to CC7 are selected by using the chip selection signals, so that the rank number viewed from the controller becomes 2. Like the LRA-1 system, the selection of the core chips CC0 to CC7 is determined during the row access, so that the number of memory cells accessed by one row, access becomes 1 kilobyte, as in the LRA-1 system. Although the chip address is not supplied during the column access, a problem is not caused with this situation, as in the LRA-1 system.

In this system, the core chips CC0 to CC3 and the core chips CC4 to CC7 are identified by the chip selection signals CS0 and CS1. Therefore, the banks belonging to the core chips CC0 to CC3 and the banks belonging to the core chips CC4 to CC7 are handled as different banks by the controller. Accordingly, the bank 0 in the core chip CC2 and the bank 0 in the core chip CC7 can be simultaneously brought into the active state as in the example in FIG. 5.

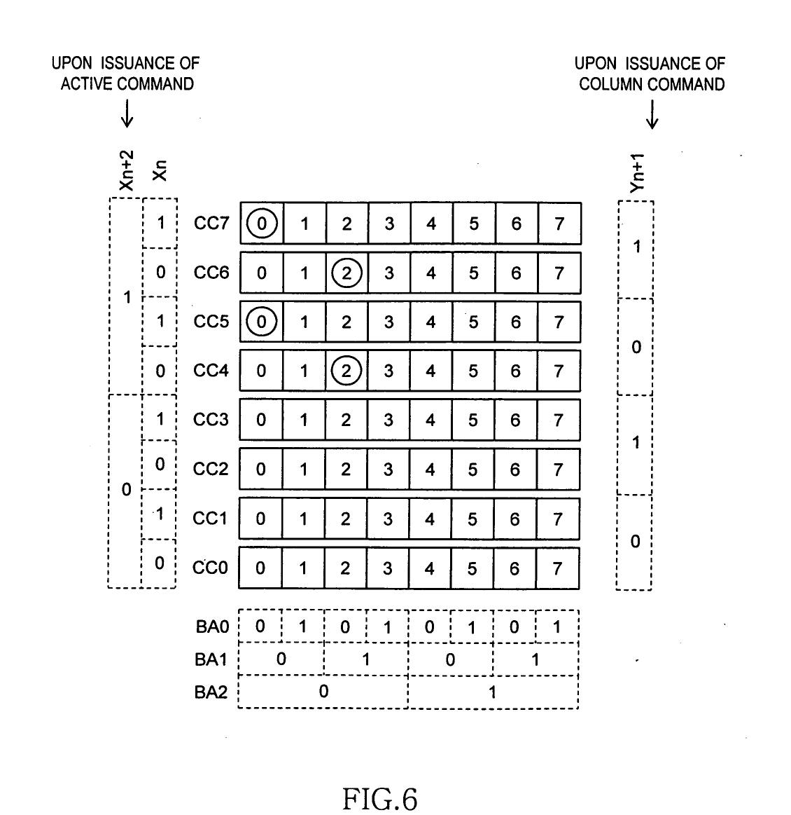

FIG. 6 is a schematic view for describing the address allocation in the LRA-3 system.

As illustrated in FIG. 6, in the LRA-3 system, any one set of the core chips CC0 and CC2, the core chips CC1 and CC3, the core chips CC4 and CC6, and the core chips CC5 and CC7 is selected based upon a part of the address signals, which is Xn+2 and Xn, supplied during the row access, and either one of the selected two core chips is selected based upon a part of the address signals, which is Yn+1, supplied during the column access. The bank address signals BA0 to BA2 are supplied during both the row access and the column access.

In this system, the selection of the core chips CC0 to CC7 is made based upon the part of the address signals, which is Xn+2 and Xn, supplied during the row access, and a part of the address signals, which is Yn+1, supplied during the column access. Therefore, the chip address becomes Xn+2, Xn, and Yn+1. Since two core chips are in the active state during the row access, the number of memory cells accessed by one row access becomes double that in the LRA-1 system and LRA-2 system. For example, it becomes 2 kilobytes. The rank number is 1, as in the LRA-1 system.

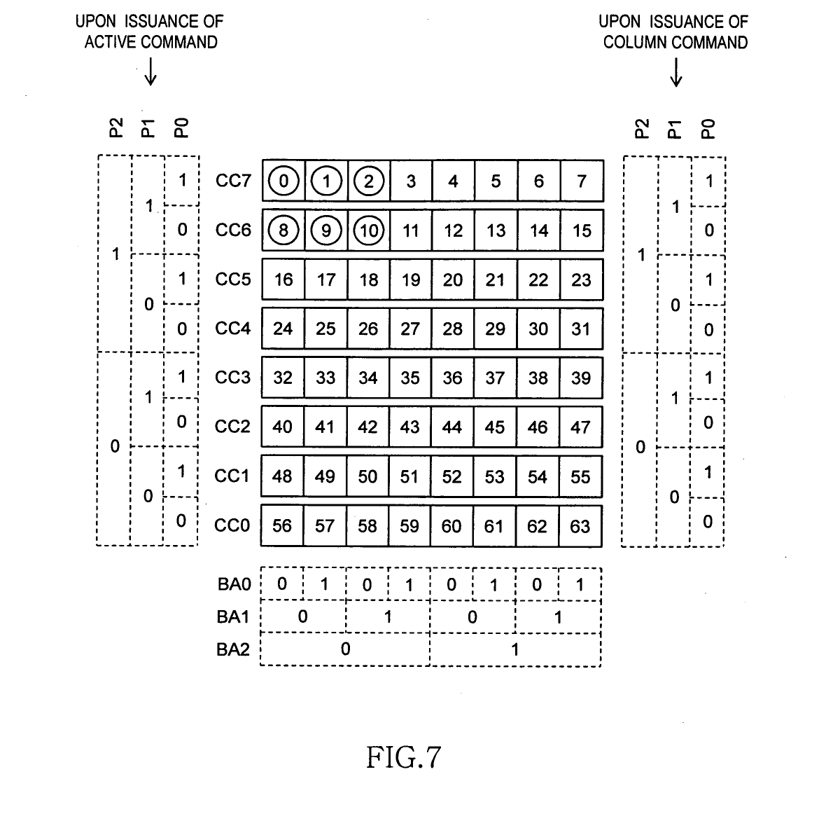

FIG. 7 is a schematic view for describing the address allocation in the PRA system.

As illustrated in FIG. 7, the PRA system is the one in which chip addresses P2, P1, and P0, which are a part of the address signal, and the bank address signals BA0 to BA2 are supplied during both the row access and the column access. In this system, the controller recognizes all banks as different banks. Specifically, the controller recognizes 64 banks in the present embodiment. Therefore, the number and the combination of the banks, which become the active state, is optional, wherein the maximum of 64 banks can be brought into the active state.

The above description is the detail of the respective address allocation systems. The address allocation systems can be changed by the mode selection.

A specific circuit structure of the semiconductor device 10 will be described next. In the description below, the case where the operation mode of the semiconductor device 10 is set to be the LRA-2 system is taken as an example.

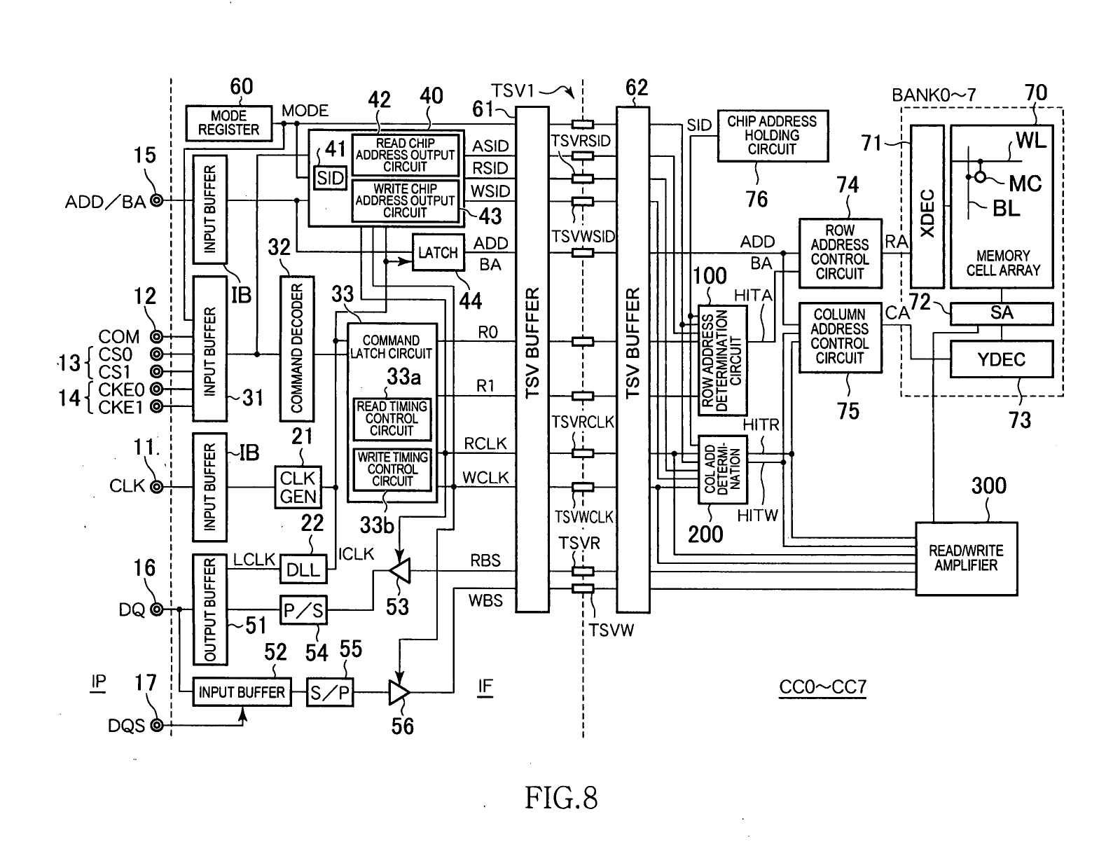

FIG. 8 is a block diagram illustrating a configuration of the semiconductor device according to a preferable embodiment of the present invention.

As illustrated in FIG. 8, external terminals mounted to an interposer IP include a clock terminal 11, a command terminal 12, a chip selecting terminal 13, a clock enable terminal 14, an address terminal 15, a data input/output terminal 16, and a data strobe terminal 17. A calibration terminal, a power supply terminal, and the like are also mounted, but these are not illustrated in the figure. All of the external terminals except for the power supply terminal are connected to the interface chip IF, and are not directly connected to the core chips CC0 to CC7.

An external clock signal CK is supplied to the clock terminal 11. The supplied external clock signal CK is supplied to a clock generating circuit 21 through an input buffer IB. The clock generating circuit 21 generates an internal clock signal ICLK. The generated internal clock signal ICLK is supplied to various circuit blocks in the interface chip IF.

The internal clock signal ICLK is supplied to a DLL circuit 22. The DLL circuit 22 generates an output clock signal LCLK. The generated output clock signal LCLK is supplied to an output buffer circuit 51.

The command terminal 12 is a terminal to which a command signal COM including a row address strobe signal RASB, a column address strobe signal CASB, and a write enable signal WEB is supplied. The chip selecting terminal 13 is a terminal to which the chip selection signals CS0B and CS1B are supplied, while the clock enable terminal 14 is a terminal to which clock enable signals CKE0 and CKE1 are supplied. These command signals, chip selection signals, and clock enable signals are supplied to a command decoder 32 through the input buffer 31.

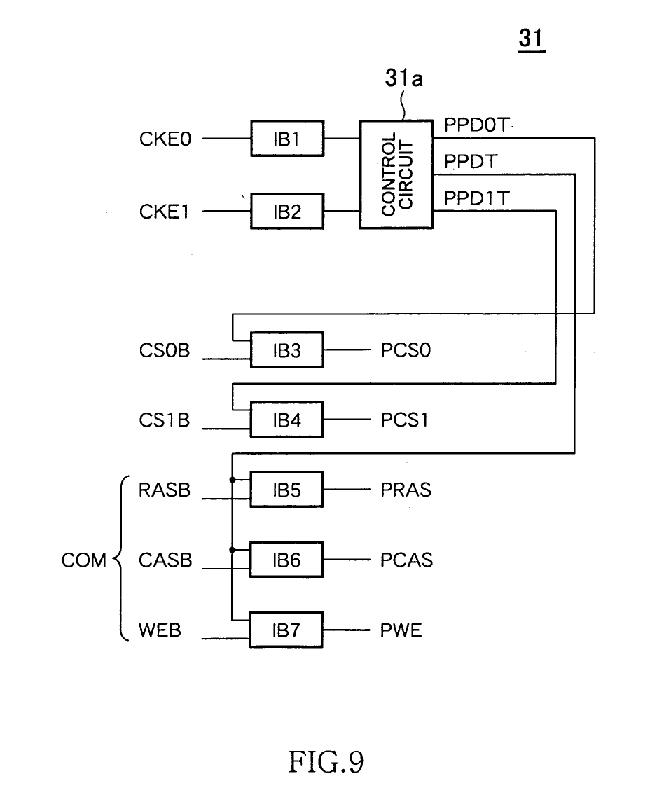

FIG. 9 is a circuit diagram of the input buffer 31.

As illustrated in FIG. 9, the input buffer 31 includes input buffers IB1 to IB7 to which the chip selection signals CS0B and CS1B, the clock enable signals CKE0 and CKE1, the row address strobe signal RASB, the column address strobe signal CASB, and the write enable signal WEB are respectively inputted. The input buffer 31 also includes a control circuit 31a that generates internal signals PPD, PPD0, and PPD1 on receipt of the clock enable signals CKE0 and CKE1 passing through the input buffers IB1 and IB2. The internal signals PPD0 and PPD1 are used as signals for activating the input buffers IB3 and IB4, while the internal signal PPD is used as a signal for activating the input buffers IB5 to IB7.

The internal signals PPD0 and PPD1 are signals that are activated based upon the chip selection signals CS0B and CS1B respectively. This structure prevents the output from the input buffer IB3 or IB4, corresponding to the chip selection signal CS0B or CS1B that is in a non-active state, from being erroneously activated. The internal signal PPD is a signal that is activated when one of the chip selection signals CS0B and CS1B is activated. Thus, if one of the chip selection signals CS0B and CS1B is activated, the input buffers IB5 to IB7 are activated. The command signals PCS0, PCS1, PRAS, PCAS, and PWE passing through the input buffers IB3 to 1B7 are supplied to the command decoder 32 illustrated in FIG. 8.

The command decoder 32 decodes the command signals PCS0, PCS1, PRAS, PCAS, and PWE outputted from the input buffer 31 so as to generate various internal control signals, and supplies these signals to a command latch circuit 33.

The command latch circuit 33 latches the various internal control signals supplied from the command decoder 32 in synchronism with the internal clock signal ICLK, and supplies the latched control signals to the core chips CC0 to CC7 through a TSV buffer 61. The control signals outputted from the command latch circuit 33 include row commands R0 and R1, a read timing signal RCLK, and a write timing signal WCLK. The read timing signal RCLK is generated by a read timing control circuit 33a included in the command latch circuit 33, and is commonly supplied to the core chips CC0 to CC7 through the TSV buffer 61 and a through silicon via TSVRCLK. The write timing signal WCLK is generated by a write timing control circuit 33b included in the command latch circuit 33, and is commonly supplied to the core chips CC0 to CC7 through the TSV buffer 61 and a through silicon via TSVWCLK.

The row command R0 is a signal that is activated when an active command ACT is issued with the state in which the chip selection signal CS0B is activated. On the other hand, the row command R1 is a signal that is activated when the active command ACT is issued with the state in which the chip selection signal CS1B is activated. This is limited to the case where the semiconductor device according to the present embodiment operates with the LRA-2 system. When the semiconductor device operates with the other system, the chip selection signal CS1B is not used, so that only the row command R0 is used.

The read timing signal RCLK is a signal that is activated after a predetermined latency has elapsed after the read command RD is issued. The latency of the read timing signal RCLK is set to be additive latency AL+α. The α corresponds to a delay time by an operation of a later-described read/write amplifier 300. The write timing signal WCLK is a signal that is activated after a predetermined latency has elapsed after the write command WR is issued. The latency of the write timing signal WCLK is set to be additive latency AL+CAS write latency CWL+β. The β corresponds to a delay time by an operation of a later-described serial/parallel conversion circuit 55. The period from when the read command RD is issued to when the read timing signal RCLK is activated, or the period from when the write command WR is issued to when the write timing signal WCLK is activated can be changed by a set value of the mode register 60.

The address terminal 15 is a terminal to which an address signal ADD and a bank address signal BA are supplied. The supplied address signal ADD and the bank address signal BA are supplied to address latch circuits 40 and 44 through an input buffer IB. The address latch circuit 40 latches a part of the supplied address signal ADD and the bank address signal BA in synchronism with the internal clock signal ICLK, and commonly supplies a chip address, which is extracted or generated from the latched address, to the core chips CC0 to CC7 through the TSV buffer 61 and the through silicon via TSV. The address latch circuit 44 also latches another part of the address signal ADD and the bank address signal BA in synchronism with the internal clock signal ICLK, and commonly supplies the latched address to the core chips CC0 to CC7 through the TSV buffer 61 and the through silicon via TSV.

As illustrated in FIG. 8, the address latch circuit 40 includes a chip address acquiring circuit 41, a read chip address output circuit 42, and a write chip address output circuit 43.

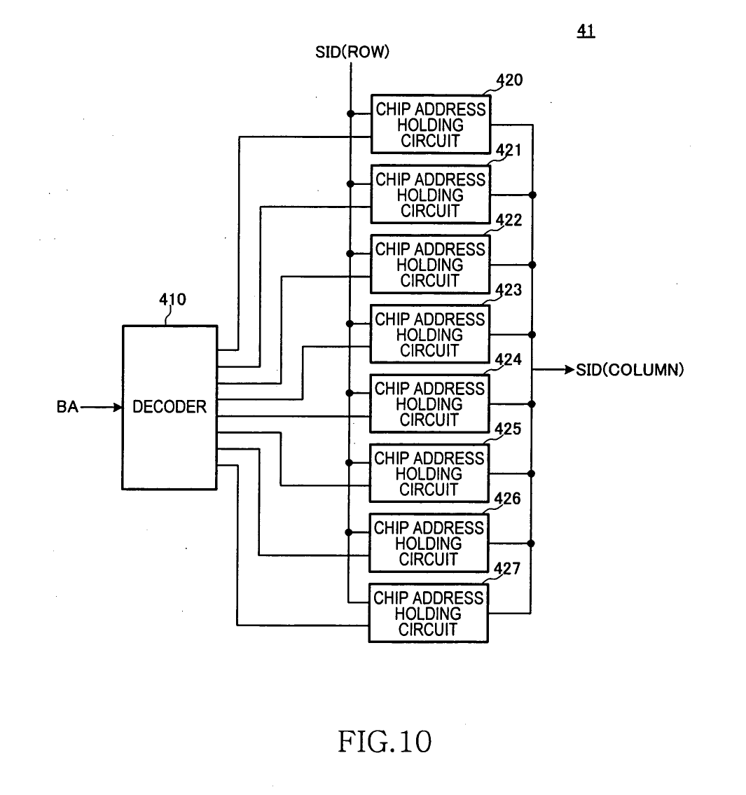

FIG. 10 is a circuit diagram of the chip address acquiring circuit 41.

As illustrated in FIG. 10, the chip address acquiring circuit 41 includes a decoder 410 that decodes the bank address BA, and chip address holding circuits 420 to 427 that holds the chip address for every bank. The decoder 410 selects any one of the chip address holding circuits 420 to 427 based upon the bank address BA designated upon the issuance of the active command ACT. The selected chip address holding circuit holds a chip address SID (ROW) designated upon the issuance of the active command ACT. When the chip address is read from the corresponding chip address holding circuits 420 to 427 based upon the bank address BA that is supplied upon the issuance of the column command, the chip address SID (COLUMN) can be acquired. The chip address SID (COLUMN) is an address indicating the core chips CC0 to CC7 that should be accessed upon the issuance of the column command. The reason why the chip address acquiring circuit 41 is used is because the chip address is not inputted upon the issuance of the column command in the LRA system.

The acquired chip address is transmitted to the read chip address output circuit 42 or the write chip address output circuit 43, and outputted as the read chip address RSID from the read chip address output circuit 42 in synchronism with the read timing signal RCLK upon the reading operation, while outputted as the write chip address WSID from the write chip address output circuit 43 in synchronism with the write timing signal WCLK upon the writing operation. The read chip address RSID is commonly supplied to the core chips CC0 to CC7 through the through silicon via TSVRSID, while the write chip address WSID is commonly supplied to the core chips CC0 to CC7 through the through silicon via TSVWSID. It is to be noted that the chip address is inputted even upon the issuance of the column command in the PRA system. Therefore, when the PRA system is selected, the inputted chip address is transmitted to the read chip address output circuit 42 or the write chip address output circuit 43 as being unchanged upon the issuance of the inputted column command.

On the other hand, the chip address inputted upon the issuance of the row command is outputted from the address latch circuit 40 as the active chip address ASID. The active chip address ASID, the read chip address RSID, and the write chip address WSID are commonly supplied to the core chips CC0 to CC7 through the different through silicon vias TSV.

The data input/output terminal 16 is a terminal for inputting or outputting the read data DQ or write data DQ. It is connected to an output buffer circuit 51 and an input buffer circuit 52. The output buffer circuit 51 receives the read data supplied through the read data latch circuit 53 and the parallel/serial conversion circuit 54, and outputs the read data to the data input/output terminal 16 in synchronism with the output clock signal LCLK. On the other hand, the input buffer circuit 52 receives the write data supplied through the data input/output terminal 16, and supplies the write data to the write data latch circuit 56 through the serial/parallel conversion circuit 55. The input buffer circuit 52 is operated in synchronism with the data strobe signal DQS supplied from the data strobe terminal 17. The parallel/serial conversion circuit 54 is a circuit that converts the parallel read data, supplied from the core chips CC0 to CC7 through the through silicon via TSVR, into serial data. The serial/parallel conversion circuit 55 is a circuit that converts the serial write data, supplied from the input buffer circuit 52, into parallel data.

As illustrated in FIG. 8, the read data is supplied from the core chips CC0 to CC7 through the through silicon via TSVR and the read bus RBS. The through silicon via TSVR is commonly connected to the core chips CC0 to CC7. On the other hand, the write data is supplied to the core chips CC0 to CC7 through a write bus WBS and the through silicon via TSVW. The through silicon via TSVW is commonly connected to the core chips CC0 to CC7. As described above, the through silicon via TSVR connected to the read bus RBS and the through silicon via TSVW connected to the write bus WBS are independently formed, whereby the read data and the write data are transferred through the signal paths different from each other.

The read data latch circuit 53 latches the parallel read data, transferred from the core chips CC0 to CC7 through the through silicon via TSVR, in synchronism with the read timing signal RCLK, and supplies the latched parallel read data to the parallel/serial conversion circuit 54. The write data latch circuit 56 latches the parallel write data, supplied from the serial/parallel conversion circuit 55, in synchronism with the write timing signal WCLK, and supplies the latched parallel write data to the core chips CC0 to CC7 through the through silicon via TSVW.

As described above, the parallel data, which is not subject to the serial conversion, is basically inputted and outputted among the read data latch circuit 53, the write data latch circuit 56, and the core chips CC0 to CC7. Specifically, in the stand-alone general SDRAM, the input/output of data with respect to the outside of the chip is made serial (i.e., the number of the data input/output terminal is one for 1 DQ), while the input/output of the data between the core chips CC0 to CC7 and the interface chip IF is made parallel. This is a significant different point between the normal SDRAM and the core chips CC0 to CC7. It is to be noted that inputting or outputting all pre-fetched parallel data pieces with the use of the different through silicon vias TSV is not essential. The number of the required through silicon vias TSV per 1 DQ may be reduced by performing the local parallel/serial conversion at the core chips CC0 to CC7. For example, the transfer of the read data or the write data between the interface chip IF and the core chips CC0 to CC7 may be made in twice.

The interface chip IF is provided with the mode register 60. The mode register 60 is a register to which the operation mode of the semiconductor device according to the present embodiment is set. The operation mode to be set includes the classification of the address allocation system, i.e., the classification of the LRA-1 system, LRA-2 system, LRA-3 system, and PRA system. A mode signal MODE, which is the output from the mode register 60, is supplied to the various circuit blocks, and is also supplied to the core chips CC0 to CC7 through the through silicon via TSV. For example, the input buffer 31 allows the chip selection signal CS1 and the clock enable signal CKE1 to be valid, when the mode signal MODE indicates the LRA-2 system. On the contrary, it allows the chip selection signal CS1 and the clock enable signal CKE1 to be invalid, when the mode signal MODE indicates the system other than the LRA-2 system. The address latch circuit 40 extracts a different part of the address signal ADD according to which one of the address allocation systems the mode signal MODE designates, and generates the chip address based upon the extracted signal.

The above description is about the outline of the interface chip IF. The circuit structures of the core chips CC0 to CC7 will be described next.

As illustrated in FIG. 8, the memory cell array 70 included in the core chips CC0 to CC7 is divided into 8 banks. The bank means a unit that can independently accept a command. In other words, each of the banks can independently and non-exclusively operate. In the memory cell array 70, plural word lines WL and plural bit lines BL cross one another, wherein a memory cell MC is arranged at each intersection (FIG. 8 illustrates only one word line WL, one bit line BL, and one memory cell MC). A row decoder 71 selects the word line WL. The bit line BL is connected to a corresponding sense amplifier in a sense circuit 72. A column decoder 73 selects the sense amplifier.

A row address RA is supplied to the row decoder 71 through a row address control circuit 74. The row address control circuit 74 latches the address signal ADD supplied through the through silicon via TSV and the TSV buffer 62 in response to the activation of a coincidence signal HITA, which is the output from a row address determination circuit 100. A column address CA is supplied to the column decoder 73 through a column address control circuit 75. The column address control circuit 75 latches the address signal ADD supplied through the through silicon via TSV and the TSV buffer 62 in response to the activation of a coincidence signal HITR or HITW, which is an output from a column address determination circuit 200.

The row address determination circuit 100 compares an active chip address ASID supplied from the interface chip IF through the through silicon via TSV and a unique chip address SID allocated to the corresponding core chips CC0 to CC7, and activates the coincidence signal HITA when they coincide with each other. The unique chip address SID is retained in a chip address holding circuit 76. The chip address holding circuit 76 is vertically connected among the core chips CC0 to CC7 through the through silicon via TSV2 of the type shown in FIG. 2B. With this structure, a different chip address SID is set to each of the core chips CC0 to CC7.

Row commands R0 and R1, and the mode signal MODE are also supplied to the row address determination circuit 100 through the through silicon via TSV. Thus, when the mode signal MODE indicates the LRA-2 system, the row address determination circuit 100 is activated in response to the row command R0, if the corresponding chip belongs to the rank 0, while the row address determination circuit 100 is activated in response to the row command R1, if the corresponding chip belongs to the rank 1. On the other hand, when the mode signal MODE indicates the system other than the LRA-2 system, the row command R1 is not used. Therefore, the row address determination circuit 100 is activated in response to the row command R0.

The column address determination circuit 200 compares the read chip address RSID and the write chip address WSID supplied from the interface chip IF through the through silicon vias TSVRSID and TSVWSID, and the unique chip address SID allocated to the corresponding core chips CC0 to CC7, and activates the coincidence signals HITR and HITW when they coincide with each other. The coincidence signals HITR and HITW are supplied not only to the column address control circuit 75 but also to the read/write amplifier 300.

The read/write amplifier 300 is activated by the coincidence signal HITR during the reading operation, and outputs the read data read from the memory cell array 70 to the interface chip IF in synchronism with the read timing signal RCLK. The read/write amplifier 300 is activated by the coincidence signal HITW during the writing operation, and outputs the write data transferred from the interface chip IF to the memory cell array 70 in synchronism with the write timing signal WCLK.

The above description is about the basic circuit structure of the core chips CC0 to CC7. The through silicon vias TSV illustrated in FIG. 8 are the through silicon via TSV1 of the type shown in FIG. 2A.

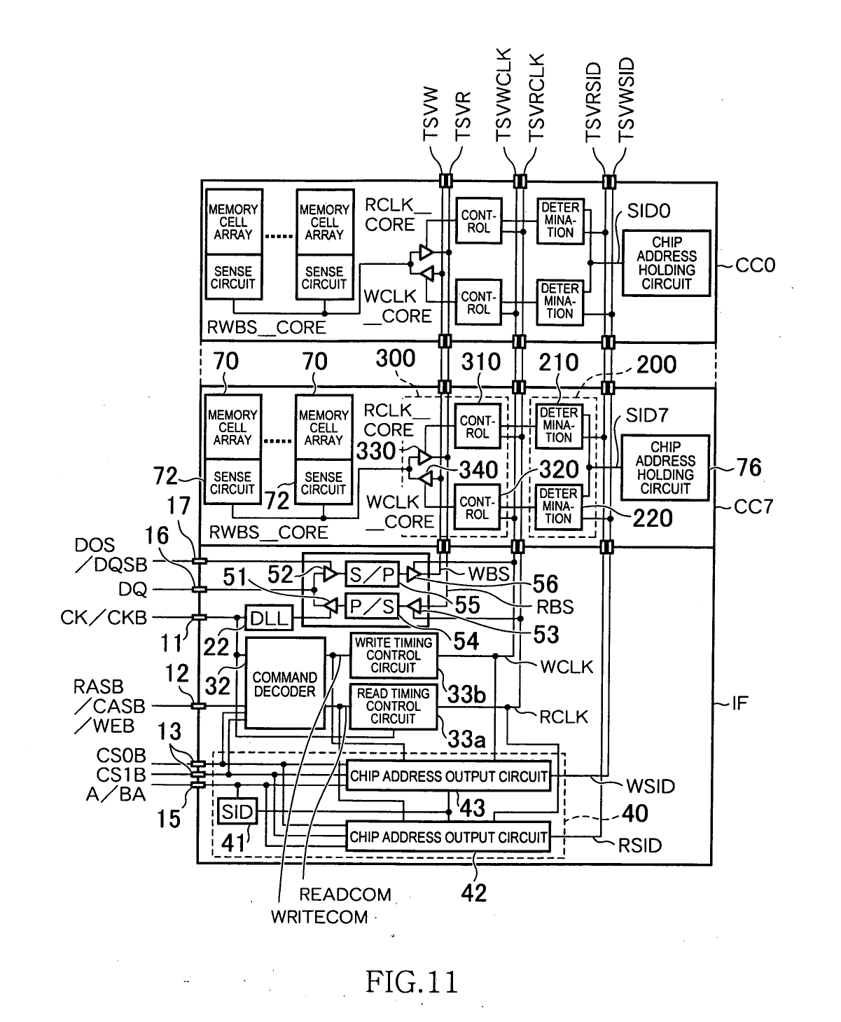

FIG. 11 is a block diagram illustrating the components, which are extracted from the semiconductor device according to the present embodiment, and which are involved with the data transfer between the interface chip IF and the core chips CC0 to CC7.

As illustrated in FIG. 11, the read chip address RSID outputted from the read chip address output circuit 42 is commonly supplied to the core chips CC0 to CC7 through the through silicon via TSVRSID. The write chip address WSID outputted from the write chip address output circuit 43 is commonly supplied to the core chips CC0 to CC7 through the through silicon via TSVWSID.

The column address determination circuit 200 provided in each of the core chips CC0 to CC7 includes a read address determination circuit 210 and a write address determination circuit 220, wherein the read chip address RSID and the write chip address WSID are respectively supplied to the determination circuits 210 and 220. Accordingly, during the reading operation, the read address determination circuit 210 compares the read chip address RSID and the unique chip address SID allocated to the corresponding core chips CC0 to CC7, and when they coincide with each other, the coincidence signal HITR is activated. On the other hand, during the writing operation, the write address determination circuit 220 compares the write chip address WSID and the unique chip address SID allocated to the corresponding core chips CC0 to CC7, and when they coincide with each other, the coincidence signal HITW is activated.

The coincidence signals HITR and HITW are respectively supplied to the read buffer control circuit 310 and the write buffer control circuit 320 included in the read/write amplifier 300. The read buffer control circuit 310 supplies a read timing signal RCLK_CORE, which is in synchronism with the read timing signal RCLK, to the read buffer 330, when the coincidence signal HITR is activated. Thus, the read data read from the sense circuit 72 is outputted to the through silicon via TSVR in synchronism with the read timing signal RCLK_CORE, and supplied to the read data latch circuit 53 through the read bus RBS. On the other hand, the write buffer control circuit 320 supplies a write timing signal WCLK_CORE, which is in synchronism with the write timing signal WCLK, to the write buffer 340, when the coincidence signal HITW is activated. Thus, the write data outputted to the through silicon via TSVW through the write bus WBS is supplied to the sense circuit 72 in synchronism with the write timing signal WCLK_CORE.

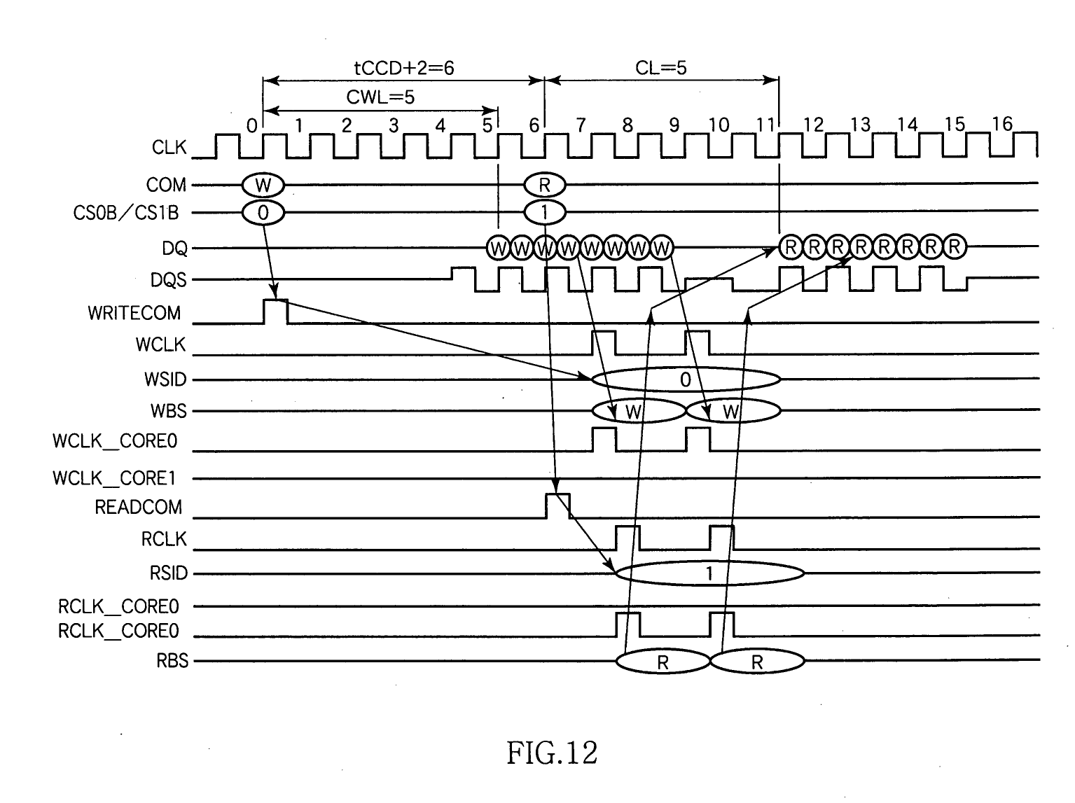

FIG. 12 is a timing chart for describing the operation of the semiconductor device according to the present embodiment.

In the example in FIG. 12, the write command W is issued in synchronism with an active edge 0 of the clock signal CK, and the read command R is issued in synchronism with an active edge 6 of the clock signal CK. The rank designated upon the issuance of the write command is the rank 0, while the rank designated upon the issuance of the read command is the rank 1. Specifically, since accesses are made to the different ranks, the memory controller can independently execute the accesses to these ranks, so long as the collision of data is not caused on the data bus.

When the write command W is issued, the command decoder 32 generates an internal write command WRITECOM, and supplies the same to the write timing control circuit 33b. The write timing control circuit 33b receives the internal write command WRITECOM, and activates the write timing signal WCLK at a predetermined timing. The period from when the internal write command WRITECOM is received to when the write timing signal WCLK is activated can be changed according to the set value of the mode register 60. The write data inputted serially after the CAS write latency CWL (=5) has elapsed from when the write command W is issued is commonly supplied to the respective core chips CC0 to CC7 through the write bus WBS and the through silicon via TSVW. The write chip address output circuit 43 commonly supplies the write chip address WSID to the respective core chips CC0 to CC7 in synchronism with the write timing signal WCLK. Thus, the write data commonly supplied to the core chips CC0 to CC7 is taken by the write buffer 340 in the core chip indicated by the write chip address WSID.

On the other hand, when the read command R is issued, the command decoder 32 generates an internal read command READCOM, and supplies the same to the read timing control circuit 33a. The read timing control circuit 33a receives the internal read command READCOM, and activates the read timing signal RCLK at a predetermined timing. The period from when the internal read command READCOM is received to when the read timing signal RCLK is activated can be changed according to the set value of the mode register 60. The read chip address output circuit 42 commonly supplies the read chip address RSID to the respective core chips CC0 to CC7 in synchronism with the read timing signal RCLK. Thus, the read data read from the memory cell array 70 in the core chip indicated by the read chip address RSID is transferred to the read bus RBS through the read buffer 330 and the through silicon via TSVR.

In the example in FIG. 12, it is understood that the operation of transferring the write data using the write bus WBS and the operation of transferring the read data using the read bus RBS are temporally overlapped. This means that the write data and the read data collide with each other on the read/write bus and the common through silicon via TSV, when the common read/write bus and the common through silicon via TSV are used. However, in the semiconductor device according to the present embodiment, the write bus WBS and the through silicon via TSVW for transferring the write data, and the read bus RBS and the through silicon via TSVR for transferring the read data are independently formed, whereby the collision of data described above is not caused. Accordingly, the use efficiency of the data bus can be enhanced.

In the above description, the writing operation and the reading operation are sequentially performed in this order between the different ranks (Write to Read). However, it can easily be understood that the collision of data is not caused even in the other cases, considering that the data transfer timings are closest in the Write to Read.

As described above, in the present embodiment, the signal path through which the write data is transferred and the signal path through which the read data is transferred are separated, whereby the collision of data is not caused even when the writing operation and the reading operation are sequentially performed in this order between the different ranks. Accordingly, the use efficiency of the data bus can be enhanced when the stacked plural core chips are operated as being classified into plural ranks.

It is apparent that the present invention is not limited to the above embodiments, but may be modified and changed without departing from the scope and spirit of the invention.

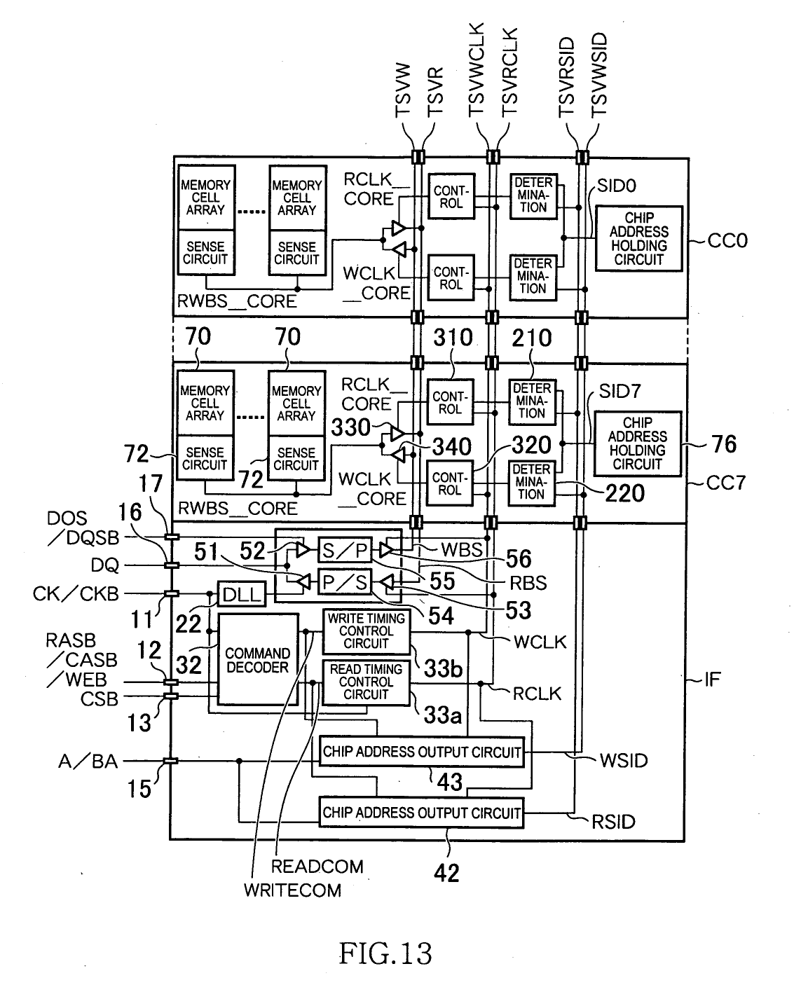

For example, the present embodiment describes the case where the semiconductor device operates with the LRA-2 system. However, it is not necessary that the semiconductor device, which is the subject of the present invention, can be operated with the LRA-2 system. Therefore, the present invention is applicable to a semiconductor device that performs a 1-rank operation as illustrated in FIG. 13. The semiconductor device illustrated in FIG. 13 performs only the 1-rank operation. Therefore, plural chip selection signals are not used, and a single chip selection signal, not illustrated, is only used. The other configuration is basically the same as that in the semiconductor device illustrated in FIG. 11.

What is claimed is:

1. A semiconductor device comprising:
a plurality of first chips that are mutually stacked, each of the first chips including a first penetration electrode that transfers write data and a second penetration electrode that transfers read data, the first penetration electrodes formed on the first chips being electrically connected in common, and the second penetration electrodes formed on the first chips being electrically connected in common; and
a second chip including a data input/output terminal, an input buffer coupled between the data input/output terminal and the first penetration electrodes, and an output buffer coupled between the data input/output terminal and the second penetration electrodes, wherein
the input buffer receiving the write data from the data input/output terminal and outputting the write data to the first penetration electrodes, and
the output buffer receiving the read data from the second penetration electrodes and outputting the read data to the data input/output terminal.

2. The semiconductor device as claimed in claim 1, wherein
each of the first chips further includes a third penetration electrode that transfers a write timing signal, a fourth penetration electrode that transfers a read timing signal, a write buffer that takes the write data supplied through the first penetration electrode in synchronism with the write timing signal, and a read buffer that supplies the read data to the second penetration electrode in synchronism with the read timing signal,
the third penetration electrodes formed on the first chips are electrically connected in common,
the fourth penetration electrodes formed on the first chips are electrically connected in common, and
the second chip further includes a command input terminal, a write timing control circuit that supplies the write timing signal to the third penetration electrodes when the command signal supplied to the command terminal indicates a write command, and a read timing control circuit that supplies the read timing signal to the fourth penetration electrodes when the command signal supplied to the command terminal indicates a read command.

3. The semiconductor device as claimed in claim 2, wherein
each of the first chips further includes a fifth penetration electrode that transfers a write chip address, a sixth penetration electrode that transfers a read chip address, a write address determination circuit that activates the write buffer when the write chip address coincides with a chip address allocated to the first chip, and a read address determination circuit that activates the read buffer when the read chip address coincides with the chip address allocated to the first chip,
the fifth penetration electrodes formed on the first chips are electrically connected in common,
the sixth penetration electrodes formed on the first chips are electrically connected in common, and
the second chip further includes a chip address acquiring circuit that acquires the write or read chip address of the first chip to be accessed, a write chip address output circuit that supplies the write chip address acquired by the chip address acquiring circuit to the fifth penetration electrodes in response to an issuance of the write command, and a read chip address output circuit that supplies the read chip address acquired by the chip address acquiring circuit to the sixth penetration electrodes in response to an issuance of the read command.

4. The semiconductor device as claimed in claim 3, wherein
the write timing control circuit supplies the write timing signal to the third penetration electrodes after a first time has elapsed from the issuance of the write command,
the read timing control circuit supplies the read timing signal to the fourth penetration electrodes after a second time has elapsed from the issuance of the read command,
the write chip address output circuit supplies the write chip address to the fifth penetration electrodes after the first time has elapsed from the issuance of the write command, and
the read chip address output circuit supplies the read chip address to the sixth penetration electrodes after the second time has elapsed from the issuance of the read command.

5. The semiconductor device as claimed in claim 4, wherein the second chip further includes a mode register that indicates the first and the second times.

6. The semiconductor device as claimed in claim 1, wherein
the first chips are grouped into a plurality of ranks,
the second chip is supplied with a plurality of chip selection signals that are exclusively activated, and
the second chip selectively activates one of the ranks corresponding to an activated one of the chip selection signals.

7. A device comprising:
a control chip including a first substrate, and first and second penetrating electrodes each penetrating the substrate; and
a memory chip stacked with the control chip;
the control chip supplying write data to the memory chip only through the first penetrating electrode;
the memory chip supplying read data to the control chip only through the second penetrating electrode.

8. The device as claimed in claim 7, wherein the control chip further includes a first write buffer coupled to the first penetrating electrode to supply the write data to the memory chip and a first read buffer coupled to the second penetrating electrode to receive the read data from the memory chip, and the memory chip including a second write buffer coupled to the first penetrating electrode to receive the write data from the control chip and a second read buffer coupled to the second penetrating electrode to supply the read data to the control chip.

9. The device as claimed in claim 8, the control chip further includes a first read/write bus coupled to each of the first read and write buffers to send/receive the write/read data and the memory chip further includes a second read/write bus coupled to each of the second read and write buffers to send/receive the write/read data.

10. The device as claimed in claim 9, wherein the memory chip further includes at least one memory cell, the write data being stored in the memory cell, and the read data being retrieved from the memory cell.

11. A device comprising:
a control chip including a first substrate, and first and second penetrating electrodes each penetrating the substrate; and
a memory chip stacked with the control chip;
the control chip supplying write data to the memory chip through the first penetrating electrode and the second penetrating electrode being free from any write data;
the memory chip supplying read data to the control chip through the second penetrating electrode and the first penetrating electrode being free from any read data.

12. The device as claimed in claim 11, further comprising an additional memory chip stacked with the memory chip, wherein the memory chip includes a second substrate, and third and fourth penetrating electrodes each penetrating the second substrate, the third and fourth penetrating electrodes being electrically coupled to the first and second penetrating electrodes, respectively, the control chip supplying another write data to the additional memory chip through the third penetrating electrode and the fourth penetrating electrode being free from any write data, and the additional memory chip supplying another read data to the control chip through the fourth penetrating electrode and the third penetrating electrode being free from any read data.
